(19) United States
(12) Patent Application Publication
(10) Pub. No.: US 2017/0170114 A1
(43) Pub. Date: Jun. 15, 2017

(54) MULTILAYER FILM INCLUDING A TANTALUM AND TITANIUM ALLOY AS A SCALABLE BARRIER DIFFUSION LAYER FOR COPPER INTERCONNECTS

(71) Applicant: Lam Research Corporation, Fremont, CA (US)

(72) Inventors: Paul Raymond Besser, Sunnyvale, CA (US); Sanjay Gopinath, Fremont, CA (US)

(21) Appl. No.: 14/969,637

(22) Filed: Dec. 15, 2015

(51) Int. Cl. H01L 23/522; H01L 23/532; C22C 14/00; H01L 21/768

(52) U.S. Cl. CPC H01L 23/5226; H01L 21/76846; H01L 21/76864; H01L 21/76871; H01L 21/76879; H01L 23/53238; C22C 14/00

(57) ABSTRACT

A method for forming a barrier diffusion layer on a substrate includes depositing a tantalum layer in features of the substrate using an atomic layer deposition process. The method includes depositing a titanium layer on the tantalum layer using an atomic layer deposition process. The method includes annealing the substrate to form the barrier diffusion layer including a tantalum-titanium alloy.

### FIELD

The present disclosure relates to substrate processing systems, and more particularly to systems and methods for depositing a multilayer film including tantalum and titanium as a scalable barrier diffusion layer for metal interconnects.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Referring now to FIG. 1, a substrate 50 includes a dielectric layer 54 and one or more underlying layers 56. Features 57 such as trenches or vias may be defined in the dielectric layer 54. A barrier diffusion stack 58 is deposited on the dielectric layer 54. The barrier diffusion stack 58 includes a tantalum nitride (TaN) layer 60 and a tantalum (Ta) layer 62. A copper seed layer 64 is deposited on the barrier diffusion stack 58. A copper bulk fill layer 66 is deposited on the copper seed layer 64.

Referring now to FIG. 2, a method 75 for filling features 57 of the substrate 50 is shown. At 80, the TaN layer 60 is deposited on the dielectric layer 54 using physical vapor deposition (PVD). At 82, the Ta layer 62 is deposited on the TaN layer 60 using PVD. At 84, the seed layer(s) 64 are deposited on the Ta layer 62 using PVD. At 86, bulk Cu fill is deposited in the features 57.

Copper (Cu) resists electromigration and has relatively low resistance. As a result, Cu has been widely used as an interconnect material. Physical vapor deposition (PVD) is typically used to deposit the barrier diffusion stack 58 including the TaN layer 60 and the Ta layer 62. The barrier diffusion stack 58 is followed by deposition of one or more PVD Cu layer(s) that serve as the seed layer(s) 64 for the Cu bulk fill layer 66. The overall thickness of the seed layer 64 and barrier diffusion stack 58 is typically 8-10 nm. Using this approach is not feasible for narrower features specified in some topologies.

### SUMMARY

A method for forming a barrier diffusion layer on a substrate includes a) depositing a tantalum layer in features of the substrate using an atomic layer deposition process; b) depositing a titanium layer on the tantalum layer using an atomic layer deposition process; and c) annealing the substrate to form the barrier diffusion layer including a tantalum-titanium alloy.

In other features, the method includes repeating both (a) and (b) one or more times before (c). The method includes (d) depositing a copper seed layer on the barrier diffusion layer. The method includes (e) performing bulk copper fill on the copper seed layer. (c) is performed before (d) and (e). (c) is performed after (d) and before (e). (c) is performed after (d) and (e).

In other features, the annealing is performed at a temperature in a temperature range from 200° C. to 450° C. The annealing is performed for a predetermined period in a range from 2 to 10 minutes. The barrier diffusion layer has a thickness that is less than 8 nm. The barrier diffusion layer has a thickness that is greater than or equal to 2 nm and less than or equal to 6 nm. The barrier diffusion layer has a thickness that is greater than or equal to 2 nm and less than or equal to 4 nm.

In other features, the method includes using a tantalum halide precursor gas to deposit the tantalum layer. The method includes using a tantalum chloride (TaCl₅) precursor gas to deposit the tantalum layer. The method includes using a titanium halide precursor gas to deposit the titanium layer. The method includes using a titanium iodide (TiI₄) precursor gas to deposit the titanium layer. After annealing, a concentration of titanium in the tantalum-titanium alloy of the barrier diffusion layer is 2-30% by atomic weight.

A method for forming a barrier diffusion stack on a substrate includes a) depositing a titanium layer in features of the substrate using an atomic layer deposition process; b) depositing a tantalum layer on the titanium layer using an atomic layer deposition process; c) depositing a titanium layer on the tantalum layer using an atomic layer deposition process; and d) annealing the substrate to form a barrier diffusion stack including a titanium oxide layer and a tantalum-titanium alloy.

In other features, the method includes, prior to (d), repeating both (b) and (c) one or more times. The method includes (e) depositing a copper seed layer on the barrier diffusion stack. The method includes (f) performing bulk copper fill on the copper seed layer. (d) is performed before (e) and (f). (d) is performed after (e) and before (f). (d) is performed after (e) and (f).

In other features, the annealing is performed at a temperature in a temperature range from 200° C. to 450° C. The annealing is performed for a predetermined period in a range from 2 to 10 minutes. The barrier diffusion stack has a thickness that is less than 8 nm. The barrier diffusion stack has a thickness that is greater than or equal to 2 nm and less than or equal to 6 nm. The barrier diffusion stack has a thickness that is greater than or equal to 2 nm and less than or equal to 4 nm.

In other features, the method includes using a tantalum halide precursor gas to deposit the tantalum layer. The method includes using a tantalum chloride (TaCl₅) precursor gas to deposit the tantalum layer. The method includes using a titanium halide precursor gas to deposit the titanium layer. The method includes using a titanium iodide (TiI₄) precursor gas to deposit the titanium layer. After annealing, a concentration of titanium in the tantalum-titanium alloy of the barrier diffusion stack is 2-30% by atomic weight.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of a substrate including features, a barrier layer, a Cu seed layer and bulk Cu fill according to the prior art;

FIG. 2 is an example of a method for filling the features of FIG. 1 according to the prior art;

FIGS. 3A-3D are side cross-sectional views of a substrate including features, a Ta—Ti barrier layer, a Cu seed layer and bulk Cu fill according to the present disclosure;

FIGS. 4A-4C are examples of methods for filling the features of FIGS. 3A-3D;

FIGS. 5A-5D are side cross-sectional views of a substrate including features, a Ti—Ta—Ti barrier layer, a Cu seed layer and bulk Cu fill according to the present disclosure; and

FIGS. 6A-6C are examples of methods for filling the features of FIGS. 5A-5D.

In the drawings, reference numbers may be reused to identify similar and/or identical elements.

### DETAILED DESCRIPTION

To enable scaling to narrower features, substrate processing systems will need to produce an ultrathin barrier diffusion layer for Cu and maximize the amount of low resistance Cu in narrow features for advanced processes. Barrier materials in the barrier diffusion layer provide a metallic interface to Cu and serve as a diffusion barrier to Cu, oxygen and water. The systems and methods according to the present disclosure use atomic layer deposition (ALD) to avoid pinch-off in narrow features and to provide a conformal barrier film of uniform thickness.

Diffusion barrier stacks or layers having a thickness less than 8-10 nm are needed for further scaling of the Cu interconnect technology. In some examples, systems and methods according to the present disclosure create a barrier diffusion layer that includes one or more Ti layers and one or more Ta layers that are annealed to create a Ta—Ti alloy layer. The resulting barrier diffusion layer has a thickness less than or equal to 8 nm. In some examples, systems and methods described herein can be used to create barrier diffusion layers that are approximately 2-6 nm thick. In some examples, systems and methods described herein can be used to create barrier diffusion layers that are approximately 2-4 nm thick. In other examples, systems and methods described herein can be used to create barrier diffusion layers that are approximately 2-3 nm thick.

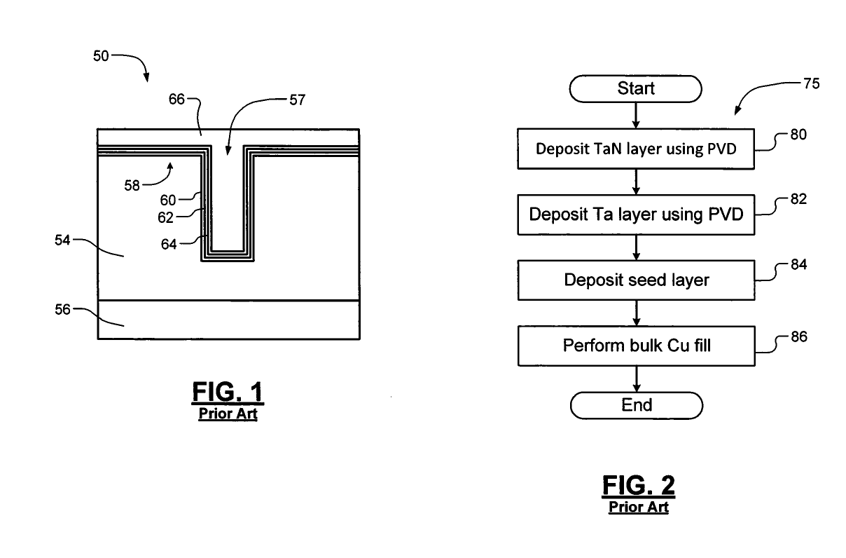

One problem encountered when modifying the barrier diffusion stack including TaN/Ta bilayers is that functions provided by both layers are generally needed. The TaN layer 60 in FIG. 1 acts as an oxygen (O), water (H₂O) and copper (Cu) diffusion layer. The Ta layer 62 in FIG. 1 acts as a Cu wetting and electromigration (EM) improvement material. Barrier-less Cu interconnects are not a viable option since most chip designers take advantage of the short-line effects associated with encapsulated Cu metal lines (leading to an infinite electromigration lifetime when the lines are shorter than the Blech Length (product of current density and line length, but also a function of k)). Barrier-less Cu interconnects would eliminate the infinite electromigration lifetime that is important to chip designers if an adjacent layer of Cu diffused into the tested metal layer (creating a “source” of Cu atoms and a flux divergence). Barrierless Cu interconnects would also be subject to moisture and O2 incorporation.

Systems and methods according to the present disclosure provide an ultrathin barrier diffusion layer for Cu interconnects. The barrier diffusion layer according to the present disclosure enables scaling to narrower features while maximizing the volume fraction of low resistance Cu in narrow features. The barrier diffusion layer according to the present disclosure provides a metallic interface to Cu and serves as a diffusion barrier to Cu, O and H₂O. Further, the barrier diffusion layer according to the present disclosure is deposited using atomic layer deposition (ALD) rather than a PVD process. As a result, pinch-off in narrow features is eliminated and a conformal barrier diffusion layer having uniform thickness is produced. Further, the barrier diffusion layer would be more conductive than the TaN/Ta bilayer

In a method according to the present disclosure, a barrier diffusion layer includes one or more bilayers. Each of the bilayers includes a Ta layer that is deposited using atomic layer deposition (ALD) and a Ti layer that is deposited using ALD. After deposition, the barrier diffusion layer is annealed to create a Ta—Ti alloy. For example, annealing at a temperature in the range of 200° C. to 450° C. for a period in the range of 2 to 10 minutes may be used. The Ta—Ti alloy provides excellent EM resistance, low resistivity, good adhesion, and serves as an excellent oxygen and water barrier.

In some examples, a Ti concentration of the barrier diffusion layer is 2-30% by atomic weight after annealing. The relative concentrations of Ta and Ti in the Ta—Ti alloy can be controlled by varying thicknesses of the individual Ta and Ti layers that are deposited.

In some examples, the precursor gases for the deposition of Ta and Ti are tantalum chloride (TaCl₅) gas and titanium iodide (TiI₄) gas, respectively. In some examples, the barrier diffusion stack is deposited with the Ti layer in contact with Cu to prevent residual chlorine in the Ta layer from contacting the Cu since residual chlorine (˜1%) in the film may corrode Cu. The Ti layer is a good material for contacting the Cu. In some examples, the Ti layer is relatively thin to minimize Ti diffusion into the Cu.

Since Ta and Ti are completely miscible over the proposed composition range, the Ta and Ti layers interdiffuse to form a single barrier of Ta—Ti alloy at all proposed compositions. The final composition of the diffusion barrier stack is controlled by varying the thicknesses and number of the individual Ta and Ti layers in the diffusion barrier stack.

In another example, the diffusion barrier stack may include a different number of Ta layers. For example, the diffusion barrier stack may include Ti—Ta—Ti or variations thereof such as Ti—Ta—Ti—Ta—Ti, etc. A Ti layer in contact with the dielectric material will form a TiO₂ layer during annealing which improves the barrier performance of the multilayer. Note that the TiO₂ will not form at the interface to metal interconnects (Cu contact) and only forms on sidewalls of the via and trench.

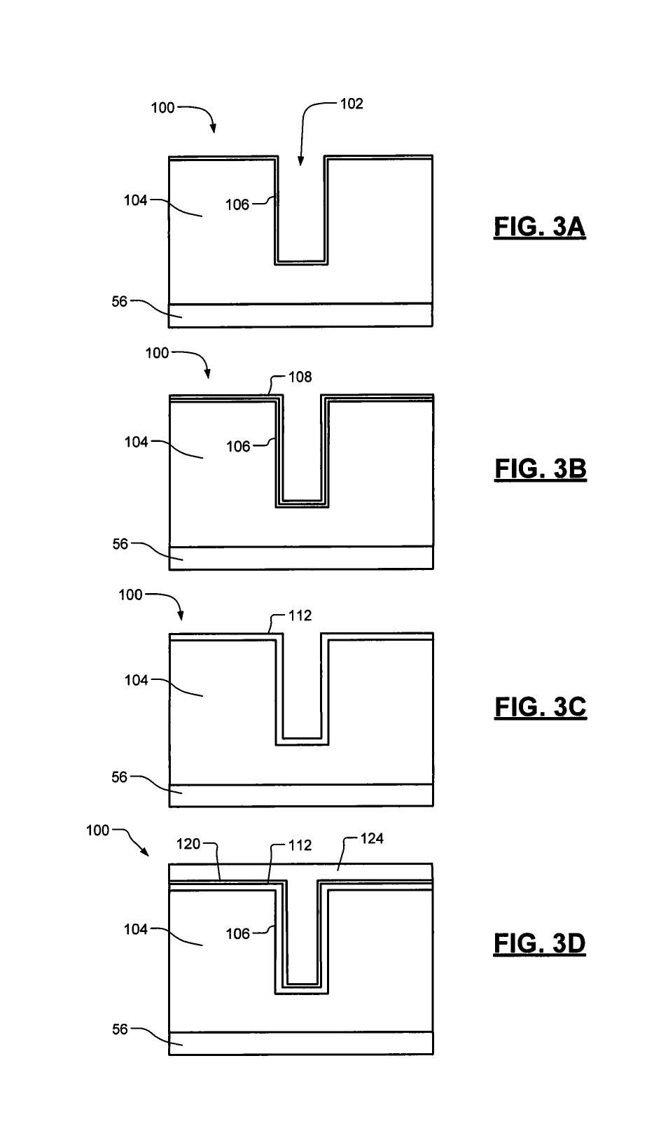

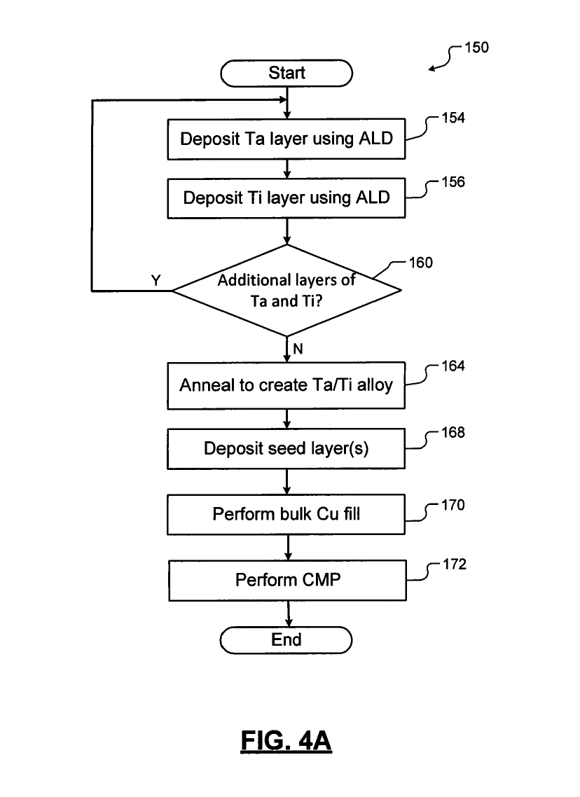

Referring now to FIG. 3A-3D, a substrate 100 including features 102 such as vias and/or trenches is shown. The substrate 100 includes a dielectric layer 104. In FIG. 3A, a Ta layer 106 is deposited on the dielectric layer 104 using one or more atomic layer deposition (ALD) cycles.

In some examples, the Ta layer 106 is deposited by adsorbing a tantalum halide on a substrate and reducing the adsorbed tantalum halide to produce tantalum as described in commonly assigned U.S. Pat. No. 7,144,806 entitled “ALD of Tantalum Using a Hydride Reducing Agent”, which issued on Dec. 5, 2006 and is hereby incorporated by reference in its entirety. For example, the tantalum halide may include tantalum pentachloride (TaCl₅), although other tantalum halides may be used. For example, the reducing agent may include a hydride such as SiH₄, SiH₆, B₂H₆ or other boron hydrides. An optional plasma treatment step may be performed after the reducing agent to remove excess halogen byproducts and unreacted halogen reactants. For example, a hydrogen plasma treatment step may be performed. If used, the plasma may be direct or remote. In some examples, chamber pressures may be in the range from 0.1 to 20 Torr (and more particularly between 0.1 to 3 Torr), although other pressures may be used. In some examples, chamber temperature may be less than 450° C. (and more particularly between 100° C. and 350° C.), although other temperatures may be used. In some examples, the tantalum halide exposure is between about 1 to 30 seconds, although other exposure periods may be used.

In FIG. 3B, a Ti layer 108 is deposited on the Ta layer 106 using one or more atomic layer deposition (ALD) cycles. In some examples, the Ti layer 108 is deposited using a titanium halide precursor. For example, the titanium halide precursor may include compounds having the formula TiXₙ, where n is an integer between and including 2 through 4, and X is a halide. Specific examples include titanium tetraiodide (TiI₄), titanium tetrachloride (TiCl₄), titanium tetrafluoride (TiF₄), titanium tetrabromide (TiBr₄), etc. Additional details may be found in commonly-assigned U.S. patent application Ser. No. 14/464,462, filed on Aug. 20, 2014, entitled “Method and Apparatus to Deposit Pure Titanium Thin Film at Low Temperature Using Titanium Tetraiodide Precursor” (Attorney Docket No. LAMRP118/3427-1US), which is hereby incorporated by reference in its entirety. If used, the plasma may be direct or remote. In some examples, each cycle includes exposing the substrate in a processing chamber to the titanium halide, purging the processing chamber, exposing the substrate to ignited plasma, purging the processing chamber and repeating to obtain a desired thickness. In some examples, chamber pressures may be in the range from 0.1 to 20 Torr (and more particularly between 0.1 to 3 Torr), although other pressures may be used. Chamber temperature may be less than 450° C. (and more particularly between 100° C. and 350° C.), although other temperatures may be used. In some examples, the titanium halide exposure is between about 1 to 30 seconds, although other exposure periods may be used. In some examples, the purging occurs for about 1 to 5 seconds, although other purge periods may be used. In some examples, the plasma exposure is about 1 to 10 seconds, although other plasma exposure periods may be used.

In some examples, the ALD processes may be repeated one or more times to deposit additional bilayers each including a Ta layer and a Ti layer. For example only, a Ta—Ti—Ta—Ti multi-layer may be deposited.

In FIG. 3C, an annealing step is performed to create a Ta—Ti alloy layer 112 at a temperature in the range of 200° C. to 450° C. for a period in the range of 2 to 10 minutes. In FIG. 3D, a Cu seed layer 120 and a Cu bulk fill layer 124 are deposited. For example, a copper electroplating process, a copper electroless plating process, a copper PVD process with reflow, or an ALD process may be used.

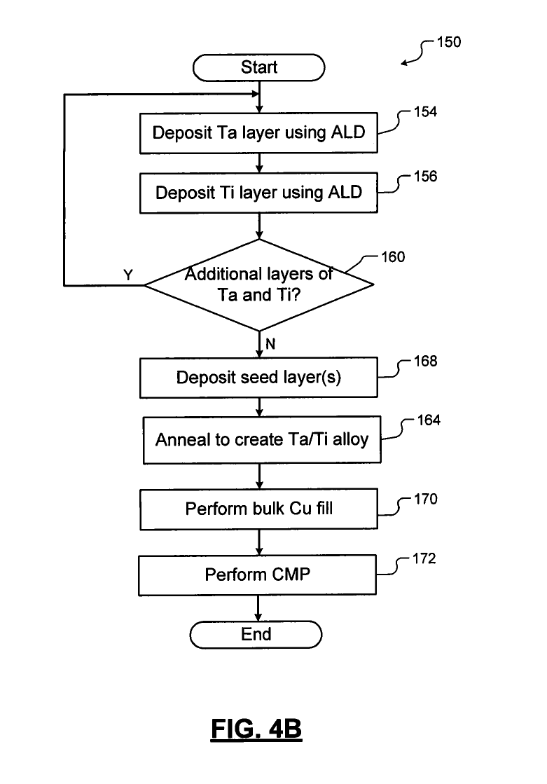

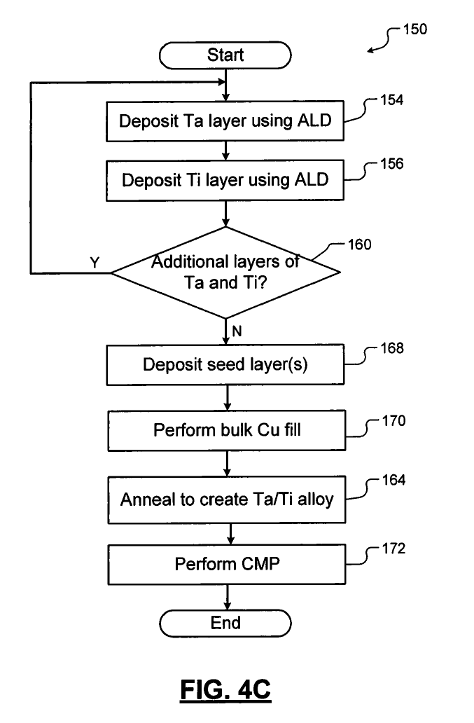

Referring now to FIGS. 4A-4C, methods 150 for creating a barrier diffusion layer is shown. At 154 in FIG. 4A, a tantalum layer is deposited using an ALD process. At 156, a titanium layer is deposited on the tantalum layer using an ALD process. At 160, one or more additional Ta—Ti bilayers may be deposited. At 164, the substrate is annealed to create a Ta/Ti alloy layer. In FIG. 4A, the annealing at 164 is performed after depositing the Ta/Ti bilayers and before depositing the seed layers, although the annealing can be performed at another time. At 168, one or more seed layers may be deposited. At 170, bulk Cu fill may be performed. At 172, chemical mechanical polishing (CMP) may be performed.

In FIG. 4B, the annealing is performed at 164 after the seed layers at 168 and before the bulk fill at 170. In FIG. 4C, the annealing at 164 is performed after the bulk fill at 170 and before CMP at 172.

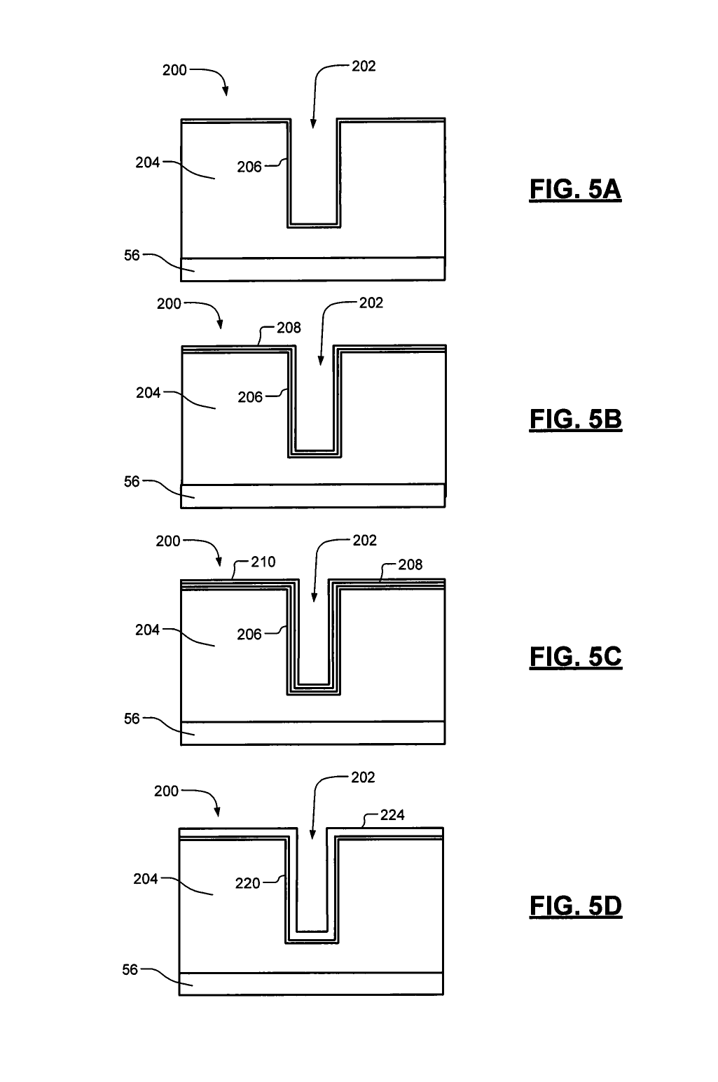

Referring now to FIG. 5A-5D, a substrate 200 including features 202 such as vias and/or trenches is shown. The substrate 200 includes a dielectric layer 204. In FIG. 5A, a Ti layer 206 is deposited on the dielectric layer 204 using an atomic layer deposition (ALD) process. In FIG. 5B, a Ta layer 208 is deposited on the Ti layer 106 using an atomic layer deposition (ALD) process. In FIG. 5C, a Ti layer 210 is deposited on the Ta layer 206 using an atomic layer deposition (ALD) process. Additional Ta—Ti bilayers may be deposited. In FIG. 5C, an annealing step is performed to create a barrier diffusion stack including a TiO₂ layer 220 (at an interface between the Ti layer 206 and the dielectric layer 204) and a Ta—Ti alloy layer 224. A Cu seed layer 120 and a Cu bulk fill layer 124 may be deposited as described in FIG. 3D above.

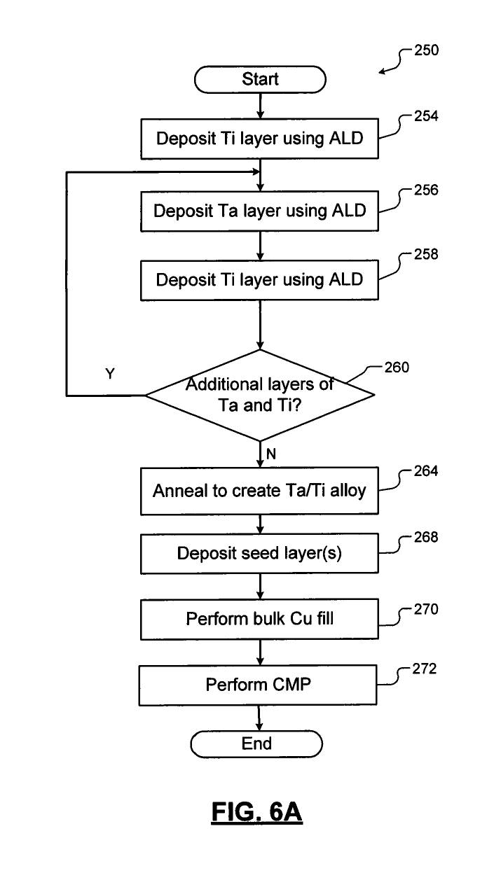

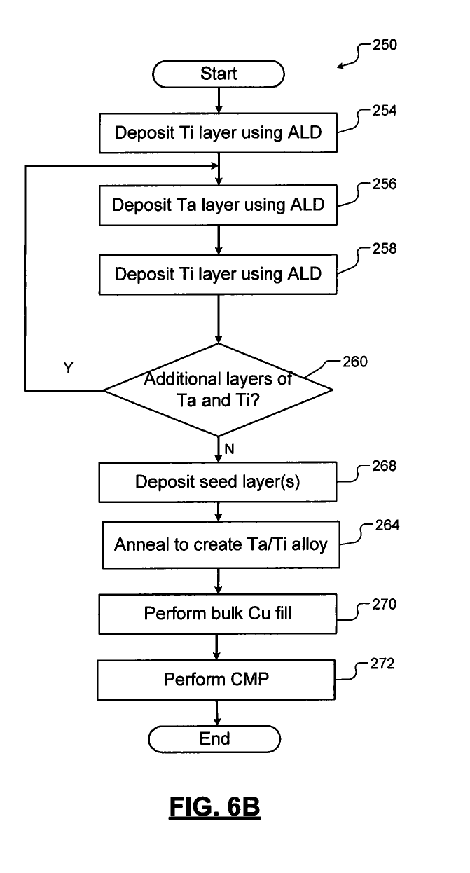

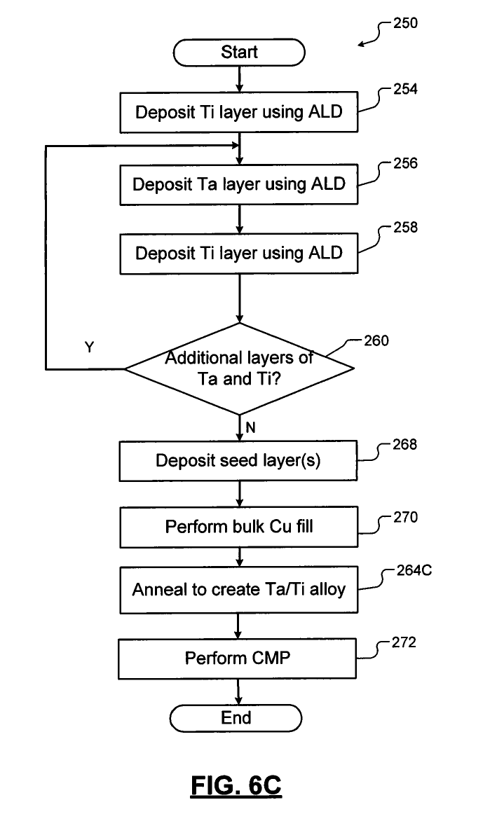

Referring now to FIGS. 6A-6C, a method for depositing a barrier diffusion stack is shown. At 254, a Ti layer is deposited using an ALD process. At 256, a Ta layer is deposited on the Ti layer using an ALD process. At 258, a Ti layer is deposited on the Ta layer. At 260, one or more additional Ta—Ti bilayers may be deposited. At 264, the substrate is annealed to create a barrier diffusion stack including a TiO₂ layer adjacent to the dielectric layer and a Ta—Ti alloy layer in other areas. In FIG. 6A, the annealing at 264 is performed after depositing the Ta/Ti bilayers and before depositing the seed layers, although the annealing can be performed at another time. At 268, one or more seed layers may be deposited. At 270, bulk Cu fill may be performed.

In FIG. 6B, the annealing is performed at 264 after the seed layers at 268 and before the bulk fill at 270. In FIG. 6C, the annealing at 264 is performed after the bulk fill at 270 and before CMP at 272.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A method for forming a barrier diffusion layer on a substrate, comprising:
a) depositing a tantalum layer in features of the substrate using an atomic layer deposition process;
b) depositing a titanium layer on the tantalum layer using an atomic layer deposition process; and
c) annealing the substrate to form the barrier diffusion layer including a tantalum-titanium alloy.

2. The method of claim 1, further comprising repeating both (a) and (b) one or more times before (c).

3. The method of claim 1, further comprising (d) depositing a copper seed layer on the barrier diffusion layer.

4. The method of claim 3, further comprising (e) performing bulk copper fill on the copper seed layer.

5. The method of claim 4, wherein (c) is performed before (d) and (e).

6. The method of claim 4, wherein (c) is performed after (d) and before (e).

7. The method of claim 4, wherein (c) is performed after (d) and (e).

8. The method of claim 1, wherein the annealing is performed at a temperature in a temperature range from 200° C. to 450° C.

9. The method of claim 1, wherein the annealing is performed for a predetermined period in a range from 2 to 10 minutes.

10. The method of claim 1, wherein the barrier diffusion layer has a thickness that is less than 8 nm.

11. The method of claim 1, wherein the barrier diffusion layer has a thickness that is greater than or equal to 2 nm and less than or equal to 6 nm.

12. The method of claim 1, wherein the barrier diffusion layer has a thickness that is greater than or equal to 2 nm and less than or equal to 4 nm.

13. The method of claim 1, further comprising using a tantalum halide precursor gas to deposit the tantalum layer.

14. The method of claim 1, further comprising using a tantalum chloride (TaCl₅) precursor gas to deposit the tantalum layer.

15. The method of claim 1, further comprising using a titanium halide precursor gas to deposit the titanium layer.

16. The method of claim 1, further comprising using a titanium iodide (TiI₄) precursor gas to deposit the titanium layer.

17. The method of claim 1, wherein, after annealing, a concentration of titanium in the tantalum-titanium alloy of the barrier diffusion layer is 2-30% by atomic weight.

18. A method for forming a barrier diffusion stack on a substrate, comprising:
a) depositing a titanium layer in features of the substrate using an atomic layer deposition process;
b) depositing a tantalum layer on the titanium layer using an atomic layer deposition process;
c) depositing a titanium layer on the tantalum layer using an atomic layer deposition process; and
d) annealing the substrate to form a barrier diffusion stack including a titanium oxide layer and a tantalum-titanium alloy.

19. The method of claim 18, wherein, prior to (d), repeating both (b) and (c) one or more times.

20. The method of claim 18, further comprising (e) depositing a copper seed layer on the barrier diffusion stack.

21. The method of claim 20, further comprising (f) performing bulk copper fill on the copper seed layer.

22. The method of claim 21, wherein (d) is performed before (e) and (f).

23. The method of claim 21, wherein (d) is performed after (e) and before (f).

24. The method of claim 21, wherein (d) is performed after (e) and (f).

25. The method of claim 18, wherein the annealing is performed at a temperature in a temperature range from 200° C. to 450° C.

26. The method of claim 18, wherein the annealing is performed for a predetermined period in a range from 2 to 10 minutes.

27. The method of claim 18, wherein the barrier diffusion stack has a thickness that is less than 8 nm.

28. The method of claim 18, wherein the barrier diffusion stack has a thickness that is greater than or equal to 2 nm and less than or equal to 6 nm.

29. The method of claim 18, wherein the barrier diffusion stack has a thickness that is greater than or equal to 2 nm and less than or equal to 4 nm.

30. The method of claim 18, further comprising using a tantalum halide precursor gas to deposit the tantalum layer.

31. The method of claim 18, further comprising using a tantalum chloride (TaCl₅) precursor gas to deposit the tantalum layer.

32. The method of claim 18, further comprising using a titanium halide precursor gas to deposit the titanium layer.

33. The method of claim 18, further comprising using a titanium iodide (TiI₄) precursor gas to deposit the titanium layer.

34. The method of claim 18, wherein, after annealing, a concentration of titanium in the tantalum-titanium alloy of the barrier diffusion stack is 2-30% by atomic weight.
